(19) United States
(12) Patent Application Publication
(10) Pub. No.: US 2026/0020482 A1
(43) Pub. Date: Jan. 15, 2026

(54) DISPLAY PANEL AND DISPLAY DEVICE

(71) Applicants: Yunnan Invensight Optoelectronics Technology Co., Ltd., Yunnan (CN); BOE Technology Group Co., Ltd., Beijing (CN)

(72) Inventors: Zhijian ZHU, Beijing (CN); Pengcheng LU, Beijing (CN); Fengxian TIAN, Beijing (CN); Shengji YANG, Beijing (CN); Kuanta HUANG, Beijing (CN); Xiaochuan CHEN, Beijing (CN); Min LIU, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 18/993,584

(22) PCT Filed: Aug. 22, 2023
(86) PCT No.: PCT/CN2023/114219

§ 371 Date: Jan. 13, 2025

(30) Foreign Application Priority Data
Sep. 23, 2022 (CN) 202211166598.2

(51) Int. Cl. H10K 59/80; H10K 59/35; H10K 59/38

(52) U.S. Cl. CPC H10K 59/879; H10K 59/352; H10K 59/38

(57) ABSTRACT

A display panel and a display device. The display panel comprises a display substrate and a microlens layer. The display substrate comprises a plurality of subpixels; the plurality of subpixels comprise first subpixels, second subpixels, and third subpixels; and at least two of the light-emitting area of the first subpixel, the light-emitting area of the second subpixel, and the light-emitting area of the third subpixel are different. The microlens layer is arranged on the light exit side of the display substrate, and the microlens layer comprises a plurality of lenses. The subpixels are located in the orthographic projections of the lenses on the display substrate, and the centers of the subpixels are arranged opposite to the centers of the lenses.

### CROSS-REFERENCE TO RELATED APPLICATIONS

The present disclosure is a national phase application of International Application No. PCT/CN2023/114219, filed on Aug. 22, 2023, which claims priority to Chinese patent application No. 202211166598.2 filed on Sep. 23, 2022, entitled “Display Panel and Display Device”, the entire contents of each are incorporated herein by reference.

### TECHNICAL FIELD

The present disclosure relates to the field of display technology, and in particular, to a display panel and a display device including the display panel.

### BACKGROUND

Micro-OLED (Micro-Organic Light-Emitting Diode) displays have the advantages of small size, light weight, high contrast, fast response speed and low power consumption.

It should be noted that, information disclosed in the above background portion is provided only for better understanding of the background of the present disclosure, and thus it may contain information that does not form the prior art known by those ordinary skilled in the art.

### SUMMARY

The purpose of the present disclosure is to provide a display panel w and a display device including the display panel.

According to one aspect of the present disclosure, there is provided a display panel, including:
a display substrate, including a plurality of sub-pixels, the plurality of sub-pixels including a first sub-pixel, a second sub-pixel and a third sub-pixel, at least two of a light-emitting areas of the first sub-pixel, a light-emitting areas of the second sub-pixel and a light-emitting areas of the third sub-pixel being different; and
a microlens layer, disposed on a light-emitting side of the display substrate, the microlens layer including a plurality of lenses, each sub-pixel is located within an orthographic projection of each lens, and a center of each sub-pixel is aligned with a center of each lens.

In an exemplary embodiment according to the disclosure, a ratio of a difference between the light-emitting area of the first sub-pixel and the light-emitting area of the second sub-pixel to the light-emitting area of the first sub-pixel is less than or equal to 5%, a ratio of a difference between the light-emitting area of the first sub-pixel and the light-emitting area of the third sub-pixel to the light-emitting area of the first sub-pixel is less than or equal to 5%, and a ratio of a difference between the light-emitting area of the second sub-pixel and the light-emitting area of the third sub-pixel to the light-emitting area of the second sub-pixel is less than or equal to 5%.

In an exemplary embodiment according to the disclosure, the plurality of lenses are same in shape and size.

In an exemplary embodiment according to the disclosure, the first sub-pixel, the second sub-pixel and the third sub-pixel are located at a focal plane of the lens.

In an exemplary embodiment according to the disclosure, the lens aligned with the first sub-pixel is a first lens, the lens aligned with the second sub-pixel is a second lens, the lens aligned with the third sub-pixel is a third lens, and a curvature radius of the first lens is not equal to a curvature radius of the second lens, and a curvature radius of the first lens is not equal to a curvature radius of the third lens.

In an exemplary embodiment according to the disclosure, the first sub-pixel is located in a focal plane of the first lens, the second sub-pixel is not located in a focal plane of the second lens, and the third sub-pixel is not located in a focal plane of the third lens.

In an exemplary embodiment according to the disclosure, a surface of the lens close to the display substrate is a plane, and a surface away from the display substrate is a convex curved surface; or a surface of the lens away from the display substrate is a plane, and a surface close to the display substrate is a convex curved surface.

In an exemplary embodiment according to the disclosure, the display panel further includes:
a color filter layer, disposed on the light-emitting side of the display substrate, wherein the color filter layer includes a plurality of filter parts, and an orthographic projection of one of the lenses on the display substrate is located within an orthographic projection of one of the filter parts on the display substrate; the microlens layer is located on a side of the color filter layer away from the display substrate, or the microlens layer is located on a side of the color filter layer close to the display substrate.

In an exemplary embodiment according to the disclosure, a gap is provided between two adjacent lenses, an overlapping portion is provided between two adjacent filter parts, a width of the overlapping portion in a first direction is greater than or equal to a maximum width of the gap in the first direction, and the first direction is parallel to a display surface of the display substrate.

In an exemplary embodiment according to the disclosure, the first subpixel, the second subpixel and the third subpixel are same in shape, a perimeter of the first subpixel is smaller than a perimeter of the second subpixel, and the perimeter of the first subpixel is smaller than a perimeter of the third subpixel.

In an exemplary embodiment according to the disclosure, the first sub-pixel, the second sub-pixel and the third sub-pixel are each configured in a ring shape, and the ring shape includes an inner ring line and an outer ring line.

In an exemplary embodiment according to the disclosure, the outer ring line of the first subpixel, the outer ring line of the second subpixel and the outer ring line of the third subpixel are same in shape and perimeter, the inner ring line of the first subpixel, the inner ring line of the second subpixel and the inner ring line of the third subpixel are same in shape, a perimeter of the inner ring line of the first subpixel is greater than a perimeter of the inner ring line of the second subpixel, and the perimeter of the inner ring line of the first subpixel is greater than a perimeter of the inner ring line of the third subpixel.

In an exemplary embodiment according to the disclosure, the inner ring line of the first sub-pixel, the inner ring line of the second sub-pixel and the inner ring line of the third sub-pixel are same in shape, and the inner ring line of the first sub-pixel, the inner ring line of the second sub-pixel and the inner ring line of the third sub-pixel are same in perimeter; the outer ring line of the first sub-pixel, the outer ring line of the second sub-pixel and the outer ring line of the third sub-pixel are same in shape, a perimeter of the outer ring line of the first sub-pixel is smaller than a perimeter of the outer ring line of the second sub-pixel, and the perimeter of the outer ring line of the first sub-pixel is smaller than a perimeter of the outer ring line of the third sub-pixel.

In an exemplary embodiment according to the disclosure, the first sub-pixel is a green sub-pixel, the second sub-pixel is a red sub-pixel, and the third sub-pixel is a blue sub-pixel; and the display substrate includes:
a base layer;
a first electrode, disposed on a side of the base layer;
a pixel definition layer, disposed on a side of the first electrode away from the base layer, wherein a first via hole is disposed on the pixel definition layer;
a light-emitting layer group, disposed on a side of the pixel definition layer away from the base layer, and at least a portion of the light-emitting layer group is located in the first via hole;
a second electrode, disposed on a side of the light-emitting layer group away from the base layer; and
a thin film encapsulation, disposed on a side of the second electrode away from the base layer.

According to another aspect of the present disclosure, there is provided a display device including any one of the above display panel.

It is to be understood that both the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for those skilled in the art, other drawings can be obtained based on these accompanying drawings without creative effort.

FIG. 1 is a schematic structural diagram of a first exemplary embodiment of a display panel according to the present disclosure.

FIG. 2 is a schematic diagram of a top view of the display substrate in FIG. 1.

FIG. 3 is a schematic graph showing that the brightness of the first sub-pixel decays with view angle.

FIG. 4 is a schematic graph showing that the brightness of the second sub-pixel decays with view angle.

FIG. 5 is a schematic graph showing that the brightness of the third sub-pixel decays with view angle.

FIG. 6 is a schematic graph showing that the brightness of the combination of RGB three colors decays with the view angle.

FIG. 7 is a schematic graph showing that the brightness of the first sub-pixel decays with the view angle according to the present disclosure.

FIG. 8 is a schematic graph showing that the brightness of the combination of RGB three colors decays with the view angle according to the present disclosure.

FIG. 9 is a schematic structural diagram of another exemplary implementation of a sub-pixel in a display panel of the present disclosure.

FIG. 10 is a schematic structural diagram of another exemplary implementation of a sub-pixel in a display panel of the present disclosure.

FIG. 11 is a schematic diagram of a top view of the display panel in FIG. 1.

FIG. 12 is a schematic diagram showing the effect of the lens on the first sub-pixel.

FIG. 13 is a schematic diagram showing the effect of the lens on the second sub-pixel or the third sub-pixel.

FIG. 14 is a schematic structural diagram of a second exemplary embodiment of a display panel according to the present disclosure.

FIG. 15 is a schematic structural diagram of a third exemplary embodiment of a display panel according to the present disclosure.

FIG. 16 is a schematic structural diagram of a fourth exemplary embodiment of a display panel according to the present disclosure.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in this specification to describe the relative relationship of one component of the illustration to another component, these terms are used in this specification only for convenience, such as according to the orientation of the examples described in the drawings. It is understood that if the device of the illustration is turned upside down, the component described as “upper” will become the component “lower”. When a structure is “on” other structures, it may mean that the structure is formed integrally on the other structure, or that the structure is “directly” disposed on the other structure, or that the structure is “indirectly” disposed on the other structure through another structure.

The terms “a”, “an”, “the”, “said” and “at least one” are used to indicate the presence of one or more elements/components/etc.; the terms “including” and “having” are used to express an open-ended inclusive meaning and mean that additional elements/components/etc. may exist in addition to the listed elements/components/etc.; the terms “first”, “second” and “third” etc. are used merely as labels and are not intended to limit the quantity of their objects.

In this application, unless otherwise clearly specified and limited, the term “connection” should be understood in a broad sense. For example, “connection” can be a fixed connection, a detachable connection, or an integral connection; it can be directly connected or indirectly connected through an intermediate medium. “And/or” is just a description of the association relationship of the associated objects, indicating that there can be three relationships. For example, A and/or B can mean: A exists alone, A and B exist at the same time, and B exists alone. In addition, the character “/” in this article generally indicates that the previous and next associated objects are in an “or” relationship.

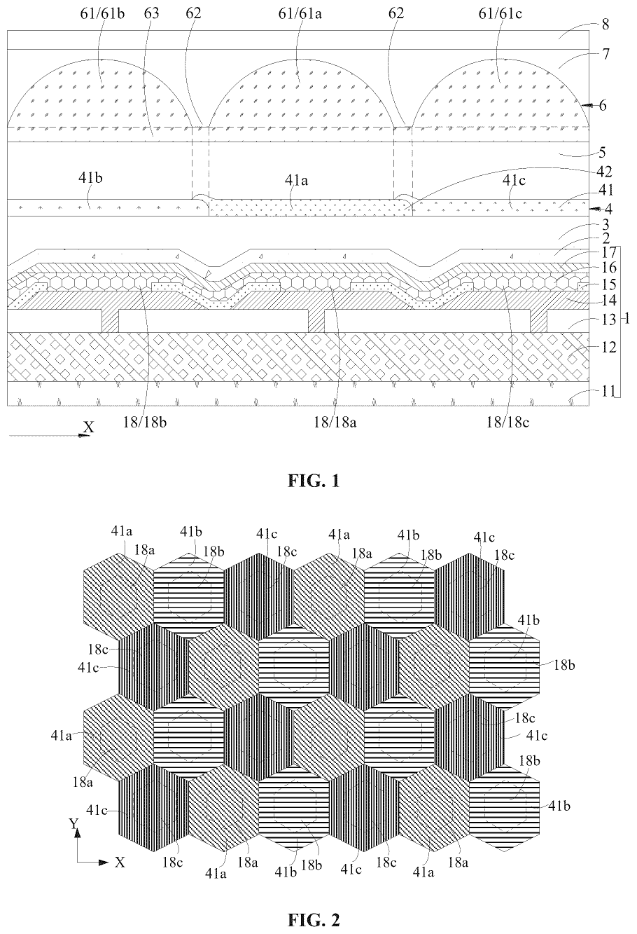

An example embodiment of the present disclosure provides a display panel, as shown in FIGS. 1 to 16, wherein the display panel may include a display substrate 1 and a microlens layer 6, wherein the display substrate 1 may include a plurality of sub-pixels 18, wherein the plurality of sub-pixels 18 include a first sub-pixel 18a, a second sub-pixel 18b, and a third sub-pixel 18c, wherein at least two of the light-emitting areas of the first sub-pixel 18a, the second sub-pixel 18b, and the third sub-pixel 18c are different; the microlens layer 6 is disposed on a light-emitting side of the display substrate 1, and the microlens layer 6 includes a plurality of lenses 61, wherein each sub-pixel 18 is located within an orthographic projection of each lens 61 on the display substrate 1, and the center of each sub-pixel 18 is aligned with the center of each lens 61.

In the display panel disclosed in the present invention, at least two light-emitting areas among the first sub-pixel 18a, the second sub-pixel 18b, and the third sub-pixel 18c are different, and the light emitted by each sub-pixel 18 is converged by each lens 61 aligned with each sub-pixel 18, thereby not only increasing the front light-emitting rate of each sub-pixel 18, increasing the brightness of the display panel, and reducing the energy consumption of the display panel; but also reducing the side light-emitting rate of each sub-pixel 18, and further improving the brightness decay rate with view angle of the sub-pixel 18 by reducing the light-emitting area of the sub-pixel 18 and the lens 61, so that a ratio of the difference between the brightness decay rate with view angle of the first sub-pixel 18a and the brightness decay rate with view angle of the second sub-pixel 18b to the brightness decay rate with view angle of the first sub-pixel 18a is less than or equal to 10%, and a ratio of the difference between the brightness decay rate with view angle of the first sub-pixel 18a and the brightness decay rate with view angle of the third sub-pixel 18c to the brightness decay rate with view angle of the first sub-pixel 18a is less than or equal to 10%. That is, the brightness decay rate with view angle of the first sub-pixel 18a, the brightness decay rate with view angle of the second sub-pixel 18b, and the brightness decay rate with view angle of the third sub-pixel 18c are substantially consistent with each other, thereby avoiding the problem of color deviation with view angle.

In this example embodiment, as shown in FIG. 1, the display panel may include a substrate layer 11, which may be a wafer, sapphire, etc. A backplane 12 is provided on a side of the substrate layer 11, and the backplane 12 may include a plurality of switch structures arranged in an array; the switch structure may include an active layer, a gate, a source, and a drain, etc.; that is, a single crystal silicon integrated circuit is used as the backplane 12. A third planarization layer 13 is provided on the side of the backplane 12 away from the substrate layer 11. The third planarization layer 13 can provide a relatively flat base plane for the first electrode 14 and the light-emitting layer group 16 formed subsequently, which is beneficial to the light-emitting effect of the light-emitting layer group 16.

A first electrode 14 is provided on the side of the third planarization layer 13 away from the substrate layer 11, and the first electrode 14 is electrically connected to the source or drain in the switch structure; the first electrode 14 can be an anode (pixel electrode). The first electrode 14 can be configured as a two-layer structure, a layer close to the third planarization layer 13 is a metal layer, and its material can be titanium, silver, etc., which can reflect light and improve the light output rate of the display panel; a layer away from the third planarization layer 13 is a high work function material layer, and the high work function material layer can include indium tin oxide (Indium-Tin-Oxide, ITO), indium zinc oxide (Indium-Zinc-Oxide, IZO), zinc oxide (ZnO) or indium oxide (In2O3), etc.; the transparent conductive layer completely covers the metal layer.

A pixel definition layer 15 is disposed on a side of the first electrode 14 away from the substrate layer 11, a first via hole is disposed on the pixel definition layer 15, and the first via hole exposes a portion of the first electrode 14. The pixel definition layer 15 may include an inorganic insulating material such as silicon oxide, silicon nitride, silicon oxynitride, hafnium oxide, aluminum oxide, titanium oxide, tantalum oxide, or zinc oxide, or may include an organic insulating material such as polyacrylate resin, epoxy resin, phenolic resin, polyamide resin, polyimide resin, unsaturated polyester resin, polyphenylene oxide resin, polyphenylene sulfide resin, or benzocyclobutene (BCB). The pixel definition layer 15 may be a single-layer film or a multi-layer film, and the multi-layer film is formed as a stack of different materials.

A light-emitting layer group 16 is disposed on the side of the pixel definition layer 15 away from the substrate layer 11 and in the first via hole. The light-emitting layer group 16 is arranged as a whole layer, completely covering the pixel definition layer 15 and the first electrode 14. The light-emitting layer group 16 in the first via hole is connected to the first electrode 14. The light-emitting layer group 16 in a first via hole emits light to form a sub-pixel 18. Therefore, the light-emitting layer group 16 in a first via hole is a sub-pixel 18, so that the orthographic projection of the sub-pixel 18 on the substrate layer 11 is the orthographic projection of the light-emitting layer group 16 in the first via hole on the substrate layer 11. The display substrate may include multiple sub-pixels 18. The shape of the sub-pixel 18 refers to the shape of the light-emitting area, the size of the sub-pixel 18 refers to the size of the light-emitting area, and the perimeter of the sub-pixel 18 refers to the perimeter of the light-emitting area.

The light-emitting layer group 16 may include a hole injection layer, a hole transport layer, a light-emitting layer, an electron transport layer and an electron injection layer stacked in sequence, the hole injection layer is in contact with the first electrode 14, and the electron injection layer is in contact with the second electrode 17. Of course, in other exemplary embodiments of the present disclosure, the light-emitting layer group 16 may include only a hole transport layer, a light-emitting layer and an electron transport layer, and the light-emitting layer group 16 may also be other structures, and its specific structure may be configured as needed.

A second electrode 17 is provided on a side of the light-emitting layer away from the substrate layer 11, and the second electrode 17 is also connected to the light-emitting layer group 16. The second electrode 17 may be a cathode (common electrode), and the second electrode 17 is connected to the ground line VSS. The second electrode 17 may be arranged in the non-light-emitting area of the sub-pixel 18 and the light-emitting area of the sub-pixel 18. That is, the second electrode 17 may be arranged over the entire surface of the plurality of sub-pixels 18. The second electrode 17 may include a low work function material layer containing Li, Ca, LiF/Ca, LiF/Al, Al, Mg, Ag, Pt, Pd, Ni, Au, Nd, Ir, Cr, BaF2, Ba, a compound thereof, or a mixture thereof (e.g., a mixture of Ag and Mg). The second electrode 17 may also include a transparent metal oxide layer arranged on the low work function material layer.

In this example embodiment, referring to FIG. 2, the cross section of the first via hole parallel to the substrate layer 11 can be configured as a regular hexagon, and the cross section of the sub-pixel 18 parallel to the substrate layer 11 can be configured as regular hexagon; of course, in other example embodiments of the present disclosure, the cross section of the first via hole parallel to the substrate layer 11 can be configured as a rectangle, a circle, other regular polygons, etc., and the corresponding cross section of the sub-pixel 18 parallel to the substrate layer 11 can be configured as a rectangle, a circle, other regular polygons, etc.

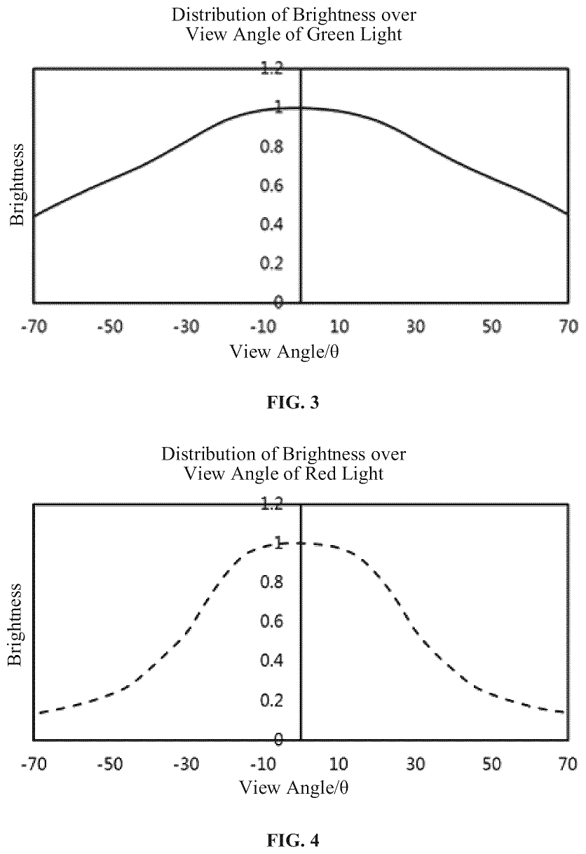

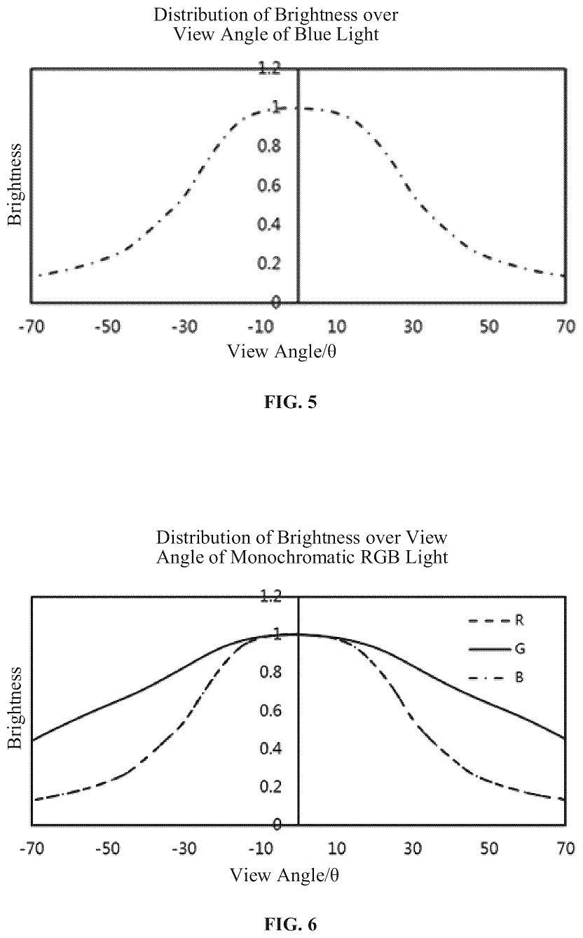

In this example embodiment, the plurality of sub-pixels 18 may include a first sub-pixel 18a, a second sub-pixel 18b, and a third sub-pixel 18c; the first sub-pixel 18a may be a green sub-pixel, the second sub-pixel 18b may be a red sub-pixel, and the third sub-pixel 18c may be a blue sub-pixel. When the light-emitting areas of the first sub-pixel 18a, the second sub-pixel 18b, and the third sub-pixel 18c are the same. Referring to FIG. 3, the brightness of the first sub-pixel 18a decays at a relatively low rate with the view angle. For example, when the view angle is about 30 degrees, the brightness of the first sub-pixel 18a can reach about 0.8; referring to FIG. 4, the brightness of the second sub-pixel 18b decays at a relatively high rate with the view angle. For example, when the view angle is also about 30 degrees, the brightness of the second sub-pixel 18b can reach about 0.5; and referring to FIG. 5, the brightness of the third sub-pixel 18c decays at a relatively high rate with the view angle. For example, when the view angle is also about 30 degrees, the brightness of the third sub-pixel 18c can also reach about 0.5. The first sub-pixel 18a, the second sub-pixel 18b and the third sub-pixel 18c form a pixel. As shown in FIG. 6, since the brightness of the first sub-pixel 18a decays at a smaller rate with the view angle, the brightness decay rate with view angle of the second sub-pixel 18b and the brightness decay rate with view angle of the third sub-pixel 18c are basically consistent with each other; for example, when the view angle is approximately 30 degrees, the brightness of the first sub-pixel 18a is relatively strong, causing the color of the pixel to be biased toward the luminous color of the first sub-pixel 18a. For example, when the first sub-pixel 18a is a green sub-pixel, the color of the pixel shifts toward green, resulting in a color deviation phenomenon.

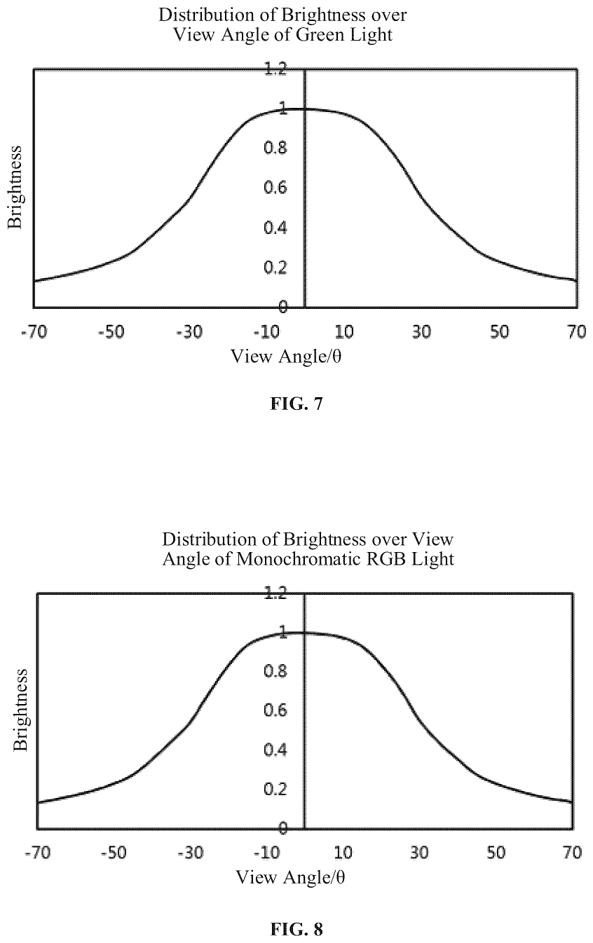

Referring to FIG. 7 and FIG. 8, the present disclosure reduces the light-emitting area of the first sub-pixel 18a so that the brightness decay rate with view angle of the first sub-pixel 18a increases, and is basically consistent with the brightness decay rate with view angle of the second sub-pixel 18b and the brightness decay rate with view angle of the third sub-pixel 18c, thereby avoiding the problem of color deviation with view angle.

Of course, in some other example embodiments of the present disclosure, when the brightness decay rate with view angle of the second sub-pixel 18b is inconsistent with the brightness decay rate with view angle of the third sub-pixel 18c, the light-emitting area of the sub-pixel with a smaller brightness decay rate with view angle can be designed to be smaller, so that the brightness decay rate with view angle of the sub-pixel increases, thereby reducing the color deviation with view angle.

The ratio of the difference between the light-emitting area of the first sub-pixel 18a and the light-emitting area of the second sub-pixel 18b to the light-emitting area of the first sub-pixel 18a is less than or equal to 5%, the ratio of the difference between the light-emitting area of the first sub-pixel 18a and the light-emitting area of the third sub-pixel 18c to the light-emitting area of the first sub-pixel 18a is less than or equal to 5%, and the ratio of the difference between the light-emitting area of the second sub-pixel 18b and the light-emitting area of the third sub-pixel to the light-emitting area of the second sub-pixel is less than or equal to 5%.

Specifically, as shown in FIG. 2, the shape of the first sub-pixel 18a, the shape of the second sub-pixel 18b and the shape of the third sub-pixel 18c are the same. For example, the first sub-pixel 18a, the second sub-pixel 18b and the third sub-pixel 18c are all configured as regular hexagons. The first sub-pixel 18a, the second sub-pixel 18b and the third sub-pixel 18c can also be configured as circles, rectangles, ellipses or various polygons. The circumference of the first sub-pixel 18a is smaller than the circumference of the second sub-pixel 18b, and the circumference of the first sub-pixel 18a is smaller than the circumference of the third sub-pixel 18c. When the first sub-pixel 18a, the second sub-pixel 18b and the third sub-pixel 18c are all set as regular hexagons, the side length of the first sub-pixel 18a is smaller than the side length of the second sub-pixel 18b, and the side length of the first sub-pixel 18a is smaller than the side length of the third sub-pixel 18c; when the first sub-pixel 18a, the second sub-pixel 18b and the third sub-pixel 18c are all set as circles, the diameter of the first sub-pixel 18a is smaller than the diameter of the second sub-pixel 18b, and the diameter of the first sub-pixel 18a is smaller than the diameter of the third sub-pixel 18c.

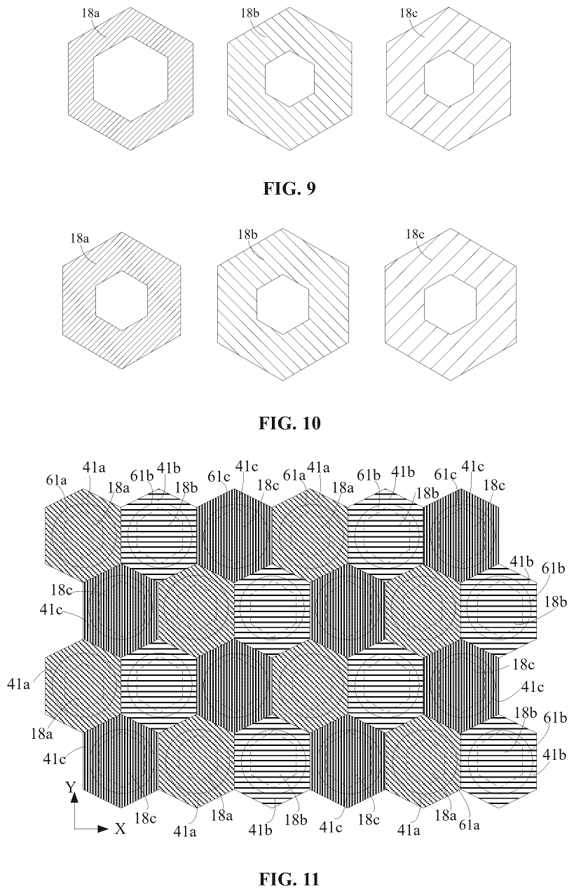

Referring to FIG. 9 and FIG. 10, in another exemplary embodiment of the present disclosure, the first sub-pixel 18a, the second sub-pixel 18b, and the third sub-pixel 18c are all configured in a ring shape, that is, the central portions of the first sub-pixel 18a, the second sub-pixel 18b, and the third sub-pixel 18c are provided with a pixel definition layer 15, rather than the light-emitting layer group 16, and the central portions of the first sub-pixel 18a, the second sub-pixel 18b, and the third sub-pixel 18c are configured as a blank area that does not emit light. The ring shape includes an inner ring line and an outer ring line. For example, the first sub-pixel 18a, the second sub-pixel 18b, and the third sub-pixel 18c can all be configured in a regular hexagonal ring shape; the first sub-pixel 18a, the second sub-pixel 18b, and the third sub-pixel 18c can also all be configured in a circular ring shape, a rectangular ring shape, an elliptical ring shape, or various polygonal ring shapes.

As shown in FIG. 9, the outer rings of the first sub-pixel 18a, the second sub-pixel 18b, and the third sub-pixel 18c have the same shape and perimeter, the inner rings of the first sub-pixel 18a, the second sub-pixel 18b, and the third sub-pixel 18c have the same shape, the perimeter of the inner ring of the first sub-pixel 18a is greater than the perimeter of the inner ring of the second sub-pixel 18b, and the perimeter of the inner ring of the first sub-pixel 18a is greater than the perimeter of the inner ring of the third sub-pixel 18c. That is, the light-emitting area of the first sub-pixel 18a is reduced by increasing the area of the non-luminous blank area in the center of the first sub-pixel 18a. For example, when the first sub-pixel 18a, the second sub-pixel 18b and the third sub-pixel 18c are all configured as regular hexagonal rings, the side length of the inner ring line of the first sub-pixel 18a is greater than the side length of the inner ring line of the second sub-pixel 18b, and the side length of the inner ring line of the first sub-pixel 18a is greater than the side length of the inner ring line of the third sub-pixel 18c; when the first sub-pixel 18a, the second sub-pixel 18b and the third sub-pixel 18c are all configured as circular rings, the diameter of the inner ring line of the first sub-pixel 18a is greater than the diameter of the inner ring line of the second sub-pixel 18b, and the diameter of the inner ring line of the first sub-pixel 18a is greater than the diameter of the inner ring line of the third sub-pixel 18c.

As shown in FIG. 10, in yet another exemplary embodiment of the present disclosure, the inner ring lines of the first sub-pixel 18a, the second sub-pixel 18b, and the third sub-pixel 18c have the same shape, and the inner ring lines of the first sub-pixel 18a, the second sub-pixel 18b, and the third sub-pixel 18c have the same perimeter. The outer ring line of the first sub-pixel 18a, the outer ring line of the second sub-pixel 18b, and the outer ring line of the third sub-pixel 18c have the same shape, the perimeter of the outer ring line of the first sub-pixel 18a is smaller than the perimeter of the outer ring line of the second sub-pixel 18b, and the perimeter of the outer ring line of the first sub-pixel 18a is smaller than the perimeter of the outer ring line of the third sub-pixel 18c. For example, when the first sub-pixel 18a, the second sub-pixel 18b and the third sub-pixel 18c are all configured as regular hexagonal rings, the side length of the outer ring line of the first sub-pixel 18a is smaller than the side length of the outer ring line of the second sub-pixel 18b, and the side length of the outer ring line of the first sub-pixel 18a is smaller than the side length of the outer ring line of the third sub-pixel 18c; when the first sub-pixel 18a, the second sub-pixel 18b and the third sub-pixel 18c are all configured as circles, the diameter of the outer ring line of the first sub-pixel 18a is smaller than the diameter of the outer ring line of the second sub-pixel 18b, and the diameter of the outer ring line of the first sub-pixel 18a is smaller than the diameter of the outer ring line of the third sub-pixel 18c.

Please continue to refer to FIG. 1. On the side of the second electrode 17 away from the substrate layer 11, a TFE (Thin Film Encapsulation 2) is provided. Because the material of the light-emitting layer and the material of the cathode are sensitive to water (H₂O) and oxygen (O₂) and are easily oxidized, the thin film encapsulation 2 can be used to isolate water and oxygen and protect the display substrate 1. The thin film encapsulation 2 may include an inorganic material layer and an organic material layer. Specifically, the encapsulation layer group may include a first inorganic layer, an organic layer disposed on a side of the first inorganic layer away from the substrate layer 11, and a second inorganic layer disposed on a side of the organic layer away from the substrate layer 11. The materials of the first inorganic layer, the organic layer, and the second inorganic layer are not described in detail here. Of course, the encapsulation layer group may also include more layers or fewer layers.

In this example embodiment, a first planarization layer 3 may be provided on the light-emitting side of the display substrate 1, that is, a first planarization layer 3 may be provided on the side of the thin film encapsulation 2 away from the substrate layer 11; a color filter layer 4 is provided on the side of the first planarization layer 3 away from the display substrate 1, that is, the first planarization layer 3 is provided between the display substrate 1 and the color filter layer 4; the first planarization layer 3 provides a relatively flat base surface for the color filter layer 4, so that the formed color filter layer 4 is more flat; and the first planarization layer 3 can increase the adhesion between the color filter layer 4 and the display substrate 1. Of course, in some other example embodiments of the present disclosure, when the flatness of the thin film encapsulation 2 is good, the first planarization layer 3 may not be provided.

In this exemplary embodiment, as shown in FIG. 1 and FIG. 2, the color filter layer 4 may include a plurality of filter parts 41, and the areas of the orthographic projections of the plurality of filter parts 41 on the display substrate are substantially the same, that is, the plurality of filter parts 41 have the same shape and substantially the same size. The plurality of filter parts 41 may include a plurality of red filter parts 41b, a plurality of green filter parts 41a, and a plurality of blue filter parts 41c. An overlapping portion 42 is provided between two adjacent filter parts 41, for example, the edge of the red filter part 41b may be lapped on the edge of the green filter part 41a, or the edge of the green filter part 41a may be lapped on the edge of the blue filter part 41c, and the lapped portions thereof form the overlapping portion 42.

As shown in FIG. 2, the filter part 41 may also be configured as a regular hexagon, so that a plurality of filter parts 41 may be densely distributed on the side of the first planarization layer 3 away from the display substrate 1. Specifically, in the first direction, the red filter part 41b, the green filter part 41a, and the blue filter part 41c are sequentially arranged and periodically arranged to form a row, and the above row of filter parts 41 are sequentially arranged in the second direction, and two adjacent rows are staggered, so that a plurality of filter parts 41 may be densely distributed. The first direction is perpendicular to the second direction. Of course, in other exemplary embodiments of the present disclosure, the cross section of the filter part 41 parallel to the substrate layer 11 may be configured as a rectangle, a circle, other regular polygons, and the like.

Referring to FIG. 2, the filter part 41 and the sub-pixel 18 are in one-to-one correspondence, that is, one filter part 41 corresponds to one sub-pixel 18. Also, the orthographic projection of the sub-pixel 18 on the substrate layer 11 is located within the orthographic projection of the filter part 41 on the substrate layer 11, that is, the area of the filter part 41 is larger than the area of the sub-pixel 18.

After filtering through the color filter layer 4, each filter part 41 can allow monochromatic red light, blue light or green light to pass through, that is, the light passing through the red filter part 41b is red light, and the light of other colors will be absorbed by the red filter part 41b; the light passing through the blue filter part 41c is blue light, and the light of other colors will be absorbed by the blue filter part 41c; the light passing through the green filter part 41a is green light, and the light of other colors will be absorbed by the green filter part 41a. As a result, the brightness of the light emitted by the sub-pixel 18 will drop significantly after passing through the color filter layer 4. Specifically, the transmittance of the color filter layer 4 is r, the AR (Aperture Ratio) of the filter part 41 is α, and the brightness of the white light emitted by the sub-pixel 18 is L, then the brightness LCF that the human eye can feel after passing through the color filter layer 4 is τ×α×L. The transmittance of the color filter layer 4 is approximately between 18% and 30%, and the aperture ratio is approximately between 60% and 70%. Calculations show that only about a quarter of the white light emitted by the sub-pixel 18 is effectively used on average, resulting in a low brightness display panel. However, the technical fields of VR and AR have very high brightness requirements for Micro OLED microdisplays due to factors such as low optical system efficiency or outdoor use.

Please continue to refer to FIG. 1, in this exemplary embodiment, a second planarization layer 5 may be provided on the side of the color filter layer 4 away from the display substrate 1, and a microlens layer 6 may be provided on the side of the second planarization layer 5 away from the display substrate 1, that is, the second planarization layer 5 may be provided between the color filter layer 4 and the microlens layer 6; the second planarization layer 5 provides a relatively flat base surface for the microlens layer 6, so that the formed microlens layer 6 is more standard, further improving the focusing effect, thereby further improving the brightness of the display panel. Of course, in some other exemplary embodiments of the present disclosure, the second planarization layer 5 may not be provided.

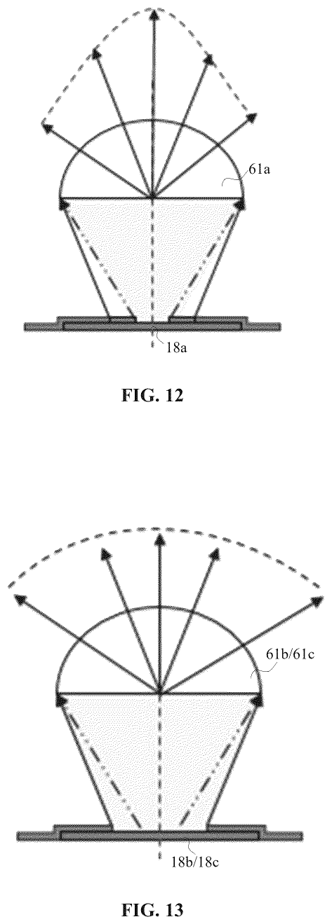

Please continue to refer to FIG. 1 and FIG. 11. In some example embodiments of the present disclosure, the microlens layer 6 may include a plurality of lenses 61, and the orthographic projection of one lens 61 on the display substrate 1 is located within the orthographic projection of one filter part 41 on the display substrate 1, that is, the lens 61 and the filter part 41 are in one-to-one correspondence, and the maximum area of the cross section of the lens 61 parallel to the display substrate 1 is less than or equal to the area of the filter part 41; and the orthographic projection of the sub-pixel 18 on the substrate layer 11 is located within the orthographic projection of the lens 61 on the substrate layer 11, that is, the maximum area of the cross section of the lens 61 parallel to the display substrate 1 is greater than or equal to the area of the sub-pixel 18.

Moreover, the center of each sub-pixel 18 is arranged relative to the center of each lens 61, that is, the center of each sub-pixel 18 is arranged directly aligned to the center of each lens 61; of course, a certain error is allowed in the alignment here, and the tolerance range varies depending on the equipment and the preparation process. Therefore, within the tolerance range of the equipment and the preparation process, it is considered to be an alignment configuration. For example, the distance between the center of the sub-pixel 18 and the center of the lens 61 in the first direction X may be less than or equal to 5% of the diameter of the lens 61.

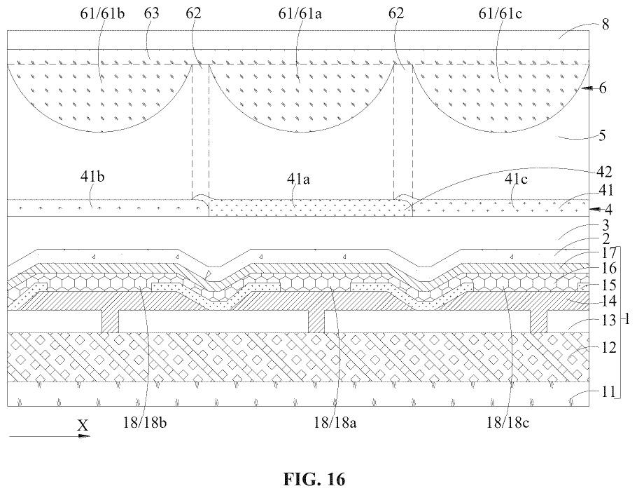

Moreover, the side of the lens 61 close to the display substrate 1 is a plane, and the lens 61 protrudes toward the side away from the display substrate 1, that is, the side of the lens 61 away from the display substrate 1 is a convex curved surface. Of course, in some other exemplary embodiments of the present disclosure, as shown in FIG. 16, the side of the lens 61 away from the display substrate 1 may be a plane, and the lens 61 protrudes toward the side close to the display substrate 1, that is, the side of the lens 61 close to the display substrate 1 is a convex curved surface.

The light emitted from the filter unit 41 can be focused by the lens 61, so that the diffusion angle of the light emitted from the lens 61 is small, thereby improving the display brightness within the effective view angle. Moreover, in order to better converge the light at a large angle, the lens 61 should be made as large as possible, so that at a certain height from the sub-pixel 18, the larger lens 61 can converge the light within a larger angle range. The preparation process of the lens 61 determines that in order to ensure that the lens 61 has a better shape (a better shape is conducive to converging light), there needs to be a certain gap 62 between two adjacent lenses 61; that is, when a gap 62 is provided between two adjacent lenses 61, the preparation process of the lens 61 will make the shape of the lens 61 more standard, thereby ensuring the convergence effect of the light and further improving the brightness. Of course, if the process allows, there may be no gap 62 between two adjacent lenses 61.

In addition, due to the manufacturing process, the microlens layer 6 may further include a flat layer 63, which is disposed on a side of the plurality of lenses 61 close to the display substrate 1, so that the sides of the plurality of lenses 61 close to the display substrate 1 are connected as a whole through the flat layer 63. Of course, if the process allows, the microlens layer 6 may not include the flat layer 63, and the plurality of lenses 61 may be spaced and separately disposed.

It should be noted that, since the lens 61 is configured as a spherical cap structure, the gap 62 between two adjacent lenses 61 is not uniform, and the width of the gap 62 in the first direction is greater than or equal to 0.2 micrometers and less than or equal to 0.8 micrometers.

Further, referring to FIG. 1, the width of the overlapped portion 42 in the first direction is equal to the maximum width of the gap 62 in the first direction, and the first direction is parallel to the display surface of the display substrate 1. Of course, the width of the overlapped portion 42 in the first direction may be greater than the maximum width of the gap 62 in the first direction.

The lens 61 may be configured as a hemisphere. Of course, in other exemplary embodiments of the present disclosure, the lens 61 may also be configured as an over-hemisphere or a sub-hemisphere. The lens 61 may be configured as a spherical cap structure so that light emitted from the filter unit 41 in all directions can be converged, thereby further improving the display brightness within the effective view angle.

In addition, when the sub-pixel 18 is a rectangle, and the rectangle includes a shorter short side and a longer long side, in order to adapt to the sub-pixel 18, the lens 61 can be configured as a semi-ellipsoid, a sub semi-ellipsoid, or an over semi-ellipsoid structure (ellipsoid cap), which can also achieve the effect of converging the light emitted from the filter unit 41 in various directions, thereby further improving the display brightness within the effective view angle. Of course, the lens 61 can be configured as a semi-cylinder, a over semi-cylinder, a sub semi-cylinder, etc.

In this exemplary embodiment, the multiple lenses 61 have the same shape and size, and the shape of the lens 61 has been described in detail above; the multiple lenses 61 have the same size, for example, when the multiple lenses 61 are spherical cap structures, the multiple lenses 61 have the same radius and the multiple lenses 61 have the same height. A portion of a sphere cut off by a plane is called a spherical cap, the cross section is called the bottom of the spherical cap, and the length of the remaining line segment after the diameter perpendicular to the cross section is cut is called the height of the spherical cap.

It should be noted that the above-mentioned sameness does not mean that it is completely the same, but has a certain error. The tolerance range varies according to the equipment and the manufacturing process. Therefore, within the tolerance range of the equipment and the manufacturing process, they are considered to be the same. For example, the difference in diameter of the two lenses 61 may be less than or equal to 1% of the diameter of one of the lenses 61.

When the plurality of lenses 61 are of an ellipsoidal cap structure, the plurality of lenses 61 also have the same size.

Moreover, the first sub-pixel 18a, the second sub-pixel 18b and the third sub-pixel 18c are all located in the focal plane of the lens 61. Specifically, the light-emitting surfaces of the first sub-pixel 18a, the second sub-pixel 18b and the third sub-pixel 18c are all located in the focal plane of the lens 61; so that the lens 61 can better transmit the light emitted by the first sub-pixel 18a, the second sub-pixel 18b and the third sub-pixel 18c, thereby further improving the light extraction efficiency of the display panel and increasing the brightness.

Moreover, the lens 61 has a different effect on the redistribution of the brightness over view angle of sub-pixels 18 with different light-emitting areas. As shown in FIG. 12, the top graph in the figure is a graph of the brightness decay rate with view angle of the first sub-pixel 18a. When the light-emitting area of the sub-pixel 18 is smaller, since the sub-pixel 18 is concentrated in the center area of the lens 61 and the center area of the lens 61 have better convergence effect, therefore, the lens 61 has a stronger convergence effect on the light emitted by the sub-pixel 18. Therefore, the decay rate of the brightness with view angle of the first sub-pixel 18a after passing through the lens 61 increases, which is basically consistent with the brightness decay rate with view angle of the second sub-pixel 18b and the brightness decay rate with view angle of the third sub-pixel 18c, thereby avoiding the problem of color deviation with view angle.

As shown in FIG. 13, the top graph in the figure is the brightness decay rate graph with view angle of the second sub-pixel 18b or the third sub-pixel 18c. When the light-emitting area of the sub-pixel 18 is larger, since the sub-pixel 18 is not only concentrated in the center area of the lens 61 but also in the edge area of the lens 61, and the center area of the lens 61 has better convergence effect while the edge area of the lens 61 has poorer the convergence effect, therefore the edge area of the lens 61 has a weaker convergence effect on the light emitted by the sub-pixel 18. Therefore, the decay rate of the brightness with view angle of the second sub-pixel 18b or the third sub-pixel 18c after passing through the lens 61 decreases, which is basically consistent with the brightness decay rate with view angle of the first sub-pixel 18a, thereby avoiding the problem of color deviation with view angle.

Of course, in some other example embodiments of the present disclosure, the first sub-pixel 18a, the second sub-pixel 18b and the third sub-pixel 18c may not be located in the focal plane of the lens 61, and the distance between the light-emitting surface of the first sub-pixel 18a, the second sub-pixel 18b and the third sub-pixel 18c and the side of the lens 61 close to the sub-pixel 18 is greater than or equal to f′/2 and less than or equal to 3 f′/2. In some display panels, the distance between the light-emitting surface of the first sub-pixel 18a, the second sub-pixel 18b and the third sub-pixel 18c and the side of the lens 61 close to the sub-pixel 18 is greater than or equal to 1 micron and less than or equal to 5 microns.

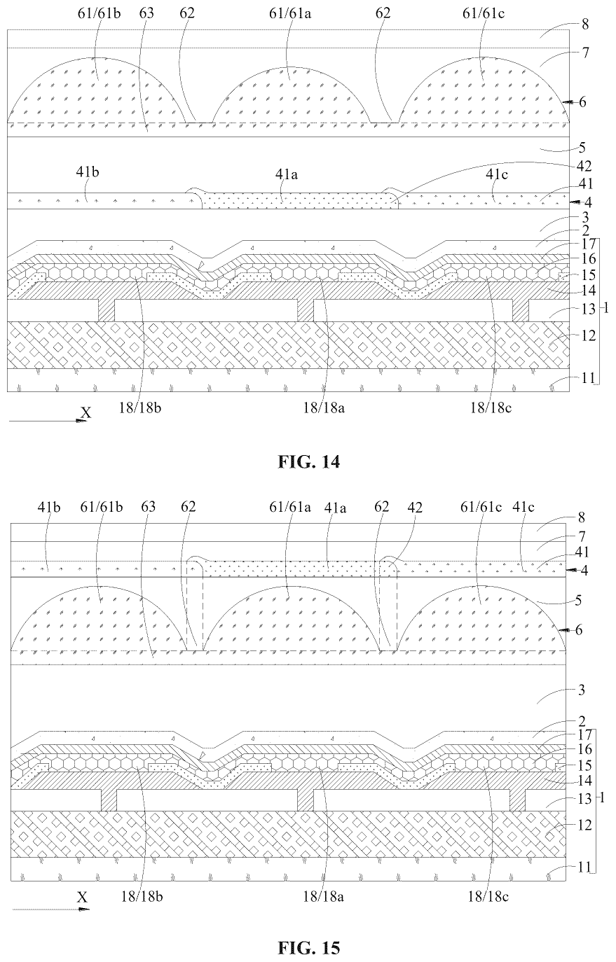

In some other example embodiments of the present disclosure, referring to FIG. 14, the lens 61 disposed corresponding to the first sub-pixel 18a is the first lens 61a, the lens 61 disposed corresponding to the second sub-pixel 18b is the second lens 61b, the lens 61 disposed corresponding to the third sub-pixel 18c is the third lens 61c, and the curvature radius of the first lens 61a is greater than the curvature radius of the second lens 61b, and the curvature radius of the first lens 61a is greater than the curvature radius of the third lens 61c.

Since the light-emitting surfaces of the plurality of sub-pixels 18 are basically arranged on the same plane, and the plurality of lenses 61 of the microlens layer 6 are formed by the same preparation process, the surface of the plurality of lenses 61 of the microlens layer 6 close to the display substrate 1 is also basically located on the same plane. In the case where the focal length of the first lens 61a is greater than the focal length of the second lens 61b, and the focal length of the first lens 61a is greater than the focal length of the third lens 61c, the first sub-pixel 18a can be located in the focal plane of the first lens 61a; and the distance between the second sub-pixel 18b and the second lens 61b is greater than the focal length of the second lens 61b, so that the second sub-pixel 18b is not located in the focal plane of the second lens 61b; and the distance between the third sub-pixel 18c and the third lens 61c is greater than the focal length of the third lens 61c, so that the third sub-pixel 18c is not located in the focal plane of the third lens 61c. In this case, the focusing ability of the second lens 61b on the light emitted by the second sub-pixel 18b decreases, and the focusing ability of the third lens 61c on the light emitted by the third sub-pixel 18c decreases, thereby slowing down the rate at which the brightness of the second sub-pixel 18b decays with the view angle, and the rate at which the brightness of the third sub-pixel 18c decays with the view angle is also slowed down, which are basically consistent with the rate at which the brightness of the first sub-pixel 18a decays with the view angle, thereby avoiding the problem of color deviation with view angle.

The focal length f′ of the lens 61 is calculated as:

$${f}^{′} = \frac{{n}_{0} \times {R}_{L}}{{n}_{L} - {n}_{0}} ,$$

wherein, n₀ is the refractive index of the adhesive layer 7 on the light-emitting side of the microlens layer 6, n_{L} is the refractive index of the lens, and R_{L} is the curvature radius of the lens 61.

From the above formula, it can be obtained that the focal length of the lens 61 is proportional to the radius of curvature. Therefore, when the radius of curvature of the first lens 61a is greater than the radius of curvature of the second lens 61b and the radius of curvature of the first lens 61a is greater than the radius of curvature of the third lens 61c, the focal length of the first lens 61a can be greater than the focal length of the second lens 61b and the focal length of the first lens 61a can be greater than the focal length of the third lens 61c.

Of course, in other exemplary embodiments of the present disclosure, the focal length of the first lens 61a may be smaller than the focal length of the second lens 61b, and the focal length of the first lens 61a may be smaller than the focal length of the third lens 61c. Similarly, when the first sub-pixel 18a is located in the focal plane of the first lens 61a, the second sub-pixel 18b is not located in the focal plane of the second lens 61b, and the third sub-pixel 18c is not located in the focal plane of the third lens 61c.

Of course, in some other example embodiments of the present disclosure, when the brightness decay rate with view angle of the second sub-pixel 18b and the brightness decay rate with view angle of the third sub-pixel 18c are inconsistent, the curvature radius or focal length of the lens 61 corresponding to the sub-pixel 18 with a smaller brightness decay rate with view angle can be configured to be smaller, and the sub-pixel 18 is located in the focal plane of the lens 61, and the curvature radius or focal length of the lens 61 corresponding to other sub-pixels 18 are configured to be larger, and the sub-pixel 18 is not located in the focal plane of the lens 61.

It should be noted that the radii of curvature of the first lens 61a, the second lens 61b and the third lens 61c cannot differ too much. Generally, the difference between the radius of curvature of the first lens 61a and the radius of curvature of the second lens 61b is less than or equal to 5% of the radius of curvature of the first lens 61a, the difference between the radius of curvature of the first lens 61a and the radius of curvature of the third lens 61c is less than or equal to 5% of the radius of curvature of the first lens 61a, and the difference between the radius of curvature of the second lens 61b and the radius of curvature of the third lens 61c is less than or equal to 5% of the radius of curvature of the second lens 61b.

Referring to FIG. 15, in another exemplary embodiment of the present disclosure, the microlens layer 6 may be located on a side of the color filter layer 4 close to the display substrate 1, that is, the microlens layer 6 is disposed between the color filter layer 4 and the display substrate 1.

Specifically, a first planarization layer 3 may be provided on the light emitting side of the display substrate 1, that is, a first planarization layer 3 may be provided on the side of the thin film encapsulation 2 away from the substrate layer 11; a microlens layer 6 is provided on the side of the first planarization layer 3 away from the display substrate 1, and a color film layer 4 is provided on the side of the microlens layer 6 away from the display substrate 1.

The specific structures of the display substrate 1, the microlens layer 6 and the color filter layer 4 have been described in detail above, and thus will not be described again here.

The microlens layer 6 is arranged on the side of the color filter layer 4 close to the display substrate 1, so that the light emitted by the display substrate 1 first passes through the microlens layer 6 and then passes through the color filter layer 4. After being converged by the microlens layer 6, the light emitted to the overlapping portion 42 is reduced, and the light emitted to the filter part 41 is increased, thereby further improving the light output efficiency of the display module.

As shown in FIG. 16, the side of the lens 61 away from the display substrate 1 may be a plane, and the lens 61 protrudes toward the side close to the display substrate 1, that is, the side of the lens 61 close to the display substrate 1 is a convex curved surface. Specifically, a recessed portion is provided on the second planarization layer 5, specifically, a recessed portion is provided on the side of the second planarization layer 5 away from the display substrate 1; a portion of the microlens layer 6 disposed in the recessed portion forms the lens 61, and a portion of the microlens layer 6 disposed outside the recessed portion forms a flat layer 63; so that the side of the formed lens 61 away from the display substrate 1 may be a plane, and the side close to the display substrate 1 is protruded.

The refractive index of the second planarization layer 5 is smaller than that of the microlens layer 6, so that the lens 61 will refract the light with a larger inclination angle incident on the interface between the second planarization layer 5 and the microlens layer 6, and the refraction angle is smaller than the incident angle, thereby converging the light with a larger inclination angle and improving the front light output efficiency of the display module.

In this exemplary embodiment, the display panel may further include an adhesive layer 7, which is disposed on a side of the microlens layer 6 away from the display substrate 1. The material of the adhesive layer 7 may be an OCA (Optically Clear Adhesive) optical glue.

In this exemplary embodiment, the display panel may further include a cover plate 8, which is disposed on a side of the adhesive layer 7 away from the display substrate 1, that is, the cover plate 8 is bonded to the microlens layer 6 through the adhesive layer 7. The cover plate 8 serves to protect the display panel.

Based on the same inventive concept, an exemplary embodiment of the present disclosure provides a display device, which may include any one of the display panels described above. The specific structure of the display panel has been described in detail above, so it will not be repeated here.

The specific type of the display device is not particularly limited, and any type of display device commonly used in the field can be used, for example, mobile devices such as mobile phones, wearable devices such as watches, AR (Augmented Reality)/VR (Virtual Reality) devices, etc. Those skilled in the art can make corresponding choices based on the specific purpose of the display device, which will not be described in detail here. In particular, AR/VR technology is becoming more mature and has received more and more attention from the consumer market and manufacturing industry. In 2025, the market share of AR/VR is expected to exceed US$100 billion.

It should be noted that, in addition to the display substrate 11, the display device also includes other necessary components and components. Taking the display as an example, it may particularly include for example a housing, a circuit board, a power cord, and the like. Those skilled in the art can make corresponding supplements according to the specific use requirements of the display device, which will not be described in detail here.

Compared with the prior art, the beneficial effects of the display device provided by the exemplary embodiment of the present disclosure are the same as the beneficial effects of the display panel provided by the above exemplary embodiment, which will not be elaborated herein.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display panel, comprising:
a display substrate, comprising a plurality of sub-pixels, the plurality of sub-pixels comprising a first sub-pixel, a second sub-pixel and a third sub-pixel, at least two of a light-emitting areas of the first sub-pixel, a light-emitting areas of the second sub-pixel and a light-emitting areas of the third sub-pixel being different; and
a microlens layer, disposed on a light-emitting side of the display substrate, the microlens layer comprising a plurality of lenses, each sub-pixel is located within an orthographic projection of each lens, and a center of each sub-pixel is aligned with a center of each lens.

2. The display panel according to claim 1, wherein a ratio of a difference between the light-emitting area of the first sub-pixel and the light-emitting area of the second sub-pixel to the light-emitting area of the first sub-pixel is less than or equal to 5%, a ratio of a difference between the light-emitting area of the first sub-pixel and the light-emitting area of the third sub-pixel to the light-emitting area of the first sub-pixel is less than or equal to 5%, and a ratio of a difference between the light-emitting area of the second sub-pixel and the light-emitting area of the third sub-pixel to the light-emitting area of the second sub-pixel is less than or equal to 5%.

3. The display panel according to claim 1, wherein the plurality of lenses are same in shape and size.

4. The display panel according to claim 3, wherein the first sub-pixel, the second sub-pixel and the third sub-pixel are located at a focal plane of the lens.

5. The display panel according to claim 1, wherein the lens aligned with the first sub-pixel is a first lens, the lens aligned with the second sub-pixel is a second lens, the lens aligned with the third sub-pixel is a third lens, and a curvature radius of the first lens is not equal to a curvature radius of the second lens, and a curvature radius of the first lens is not equal to a curvature radius of the third lens.

6. The display panel according to claim 5, wherein the first sub-pixel is located in a focal plane of the first lens, the second sub-pixel is not located in a focal plane of the second lens, and the third sub-pixel is not located in a focal plane of the third lens.

7. The display panel according to claim 1, wherein a surface of the lens close to the display substrate is a plane, and a surface away from the display substrate is a convex curved surface; or a surface of the lens away from the display substrate is a plane, and a surface close to the display substrate is a convex curved surface.

8. The display panel according to claim 1, wherein the display panel further comprises:
a color filter layer, disposed on the light-emitting side of the display substrate, wherein the color filter layer comprises a plurality of filter parts, and an orthographic projection of one of the lenses on the display substrate is located within an orthographic projection of one of the filter parts on the display substrate; the microlens layer is located on a side of the color filter layer away from the display substrate, or the microlens layer is located on a side of the color filter layer close to the display substrate.

9. The display panel according to claim 8, wherein a gap is provided between two adjacent lenses, an overlapping portion is provided between two adjacent filter parts, a width of the overlapping portion in a first direction is greater than or equal to a maximum width of the gap in the first direction, and the first direction is parallel to a display surface of the display substrate.

10. The display panel according to claim 1, wherein the first subpixel, the second subpixel and the third subpixel are same in shape, a perimeter of the first subpixel is smaller than a perimeter of the second subpixel, and the perimeter of the first subpixel is smaller than a perimeter of the third subpixel.

11. The display panel according to claim 1, wherein the first sub-pixel, the second sub-pixel and the third sub-pixel are each configured in a ring shape, and the ring shape comprises an inner ring line and an outer ring line.

12. The display panel according to claim 11, wherein the outer ring line of the first subpixel, the outer ring line of the second subpixel and the outer ring line of the third subpixel are same in shape and perimeter, the inner ring line of the first subpixel, the inner ring line of the second subpixel and the inner ring line of the third subpixel are same in shape, a perimeter of the inner ring line of the first subpixel is greater than a perimeter of the inner ring line of the second subpixel, and the perimeter of the inner ring line of the first subpixel is greater than a perimeter of the inner ring line of the third subpixel.

13. The display panel according to claim 11, wherein the inner ring line of the first sub-pixel, the inner ring line of the second sub-pixel and the inner ring line of the third sub-pixel are same in shape, and the inner ring line of the first sub-pixel, the inner ring line of the second sub-pixel and the inner ring line of the third sub-pixel are same in perimeter; the outer ring line of the first sub-pixel, the outer ring line of the second sub-pixel and the outer ring line of the third sub-pixel are same in shape, a perimeter of the outer ring line of the first sub-pixel is smaller than a perimeter of the outer ring line of the second sub-pixel, and the perimeter of the outer ring line of the first sub-pixel is smaller than a perimeter of the outer ring line of the third sub-pixel.

14. The display panel according to claim 1, wherein the first sub-pixel is a green sub-pixel, the second sub-pixel is a red sub-pixel, and the third sub-pixel is a blue sub-pixel;
and the display substrate comprises:
a base layer;
a first electrode, disposed on a side of the base layer;
a pixel definition layer, disposed on a side of the first electrode away from the base layer, wherein a first via hole is disposed on the pixel definition layer;
a light-emitting layer group, disposed on a side of the pixel definition layer away from the base layer, and at least a portion of the light-emitting layer group is located in the first via hole;
a second electrode, disposed on a side of the light-emitting layer group away from the base layer; and
a thin film encapsulation, disposed on a side of the second electrode away from the base layer.

15. A display device, comprising: a display panel, wherein the display panel comprises:
a display substrate, comprising a plurality of sub-pixels, the plurality of sub-pixels comprising a first sub-pixel, a second sub-pixel and a third sub-pixel, at least two of a light-emitting areas of the first sub-pixel, a light-emitting areas of the second sub-pixel and a light-emitting areas of the third sub-pixel being different; and
a microlens layer, disposed on a light-emitting side of the display substrate, the microlens layer comprising a plurality of lenses, each sub-pixel is located within an orthographic projection of each lens, and a center of each sub-pixel is aligned with a center of each lens.

16. The display device according to claim 15, wherein a ratio of a difference between the light-emitting area of the first sub-pixel and the light-emitting area of the second sub-pixel to the light-emitting area of the first sub-pixel is less than or equal to 5%, a ratio of a difference between the light-emitting area of the first sub-pixel and the light-emitting area of the third sub-pixel to the light-emitting area of the first sub-pixel is less than or equal to 5%, and a ratio of a difference between the light-emitting area of the second sub-pixel and the light-emitting area of the third sub-pixel to the light-emitting area of the second sub-pixel is less than or equal to 5%.

17. The display device according to claim 15, wherein the plurality of lenses are same in shape and size.

18. The display device according to claim 17, wherein the first sub-pixel, the second sub-pixel and the third sub-pixel are located at a focal plane of the lens.

19. The display device according to claim 15, wherein the lens aligned with the first sub-pixel is a first lens, the lens aligned with the second sub-pixel is a second lens, the lens aligned with the third sub-pixel is a third lens, and a curvature radius of the first lens is not equal to a curvature radius of the second lens, and a curvature radius of the first lens is not equal to a curvature radius of the third lens.

20. The display device according to claim 19, wherein the first sub-pixel is located in a focal plane of the first lens, the second sub-pixel is not located in a focal plane of the second lens, and the third sub-pixel is not located in a focal plane of the third lens.
